(19) United States
(12) Patent Application Publication
(10) Pub. No.: US 2025/0340489 A1
(43) Pub. Date: Nov. 6, 2025

(54) DEPOSITION MATERIAL SUITABLE FOR PLASMA ETCHING DEVICE MEMBER ETC., AND METHOD FOR PRODUCING IT

(71) Applicant: TOCALO CO., LTD., Kobe-shi, Hyogo (JP)

(72) Inventors: Kazuo HAMASHIMA, Kobe-shi, Hyogo (JP); Ayumu YANO, Kobe-shi, Hyogo (JP); Masashi MORISASA, Kobe-shi, Hyogo (JP)

(73) Assignee: TOCALO CO., LTD., Kobe-shi, Hyogo (JP)

(21) Appl. No.: 18/690,414

(22) PCT Filed: Dec. 8, 2022
(86) PCT No.: PCT/JP2022/045242

§ 371 Date: Aug. 15, 2024

(30) Foreign Application Priority Data
Dec. 10, 2021 (JP) 2021-200979

(51) Int. Cl. C04B 35/505; C04B 35/624; C04B 35/626; C23C 4/11; C23C 4/12; C23C 14/08; H01J 37/305

(52) U.S. Cl. CPC C04B 35/505; C04B 35/624; C04B 35/62655; C04B 35/62675; C04B 35/62695; C23C 4/11; C23C 4/12; C23C 14/083; C04B 2235/3225; C04B 2235/3244; C04B 2235/3251; C04B 2235/528; C04B 2235/5436; C04B 2235/606; C04B 2235/656; C04B 2235/663; C04B 2235/762; C04B 2235/9669; H01J 37/3053

(57) ABSTRACT

To provide a Y₂O₃-containing deposition material having high plasma resistance, suitable as a plasma etching device member, and a method for producing it.

A deposition material comprising a solid solution containing a metal oxide selected from ZrO₂, HfO₂ and Nb₂O₅, and Y₂O₃, wherein when the metal oxide is ZrO₂, the ZrO₂ content is from 2 to 12 mol %, when the metal oxide is HfO₂, the HfO₂ content is from 4 to 24 mol %, and when the metal oxide is Nb₂O₅, the Nb₂O₅ content is from 1 to 8 mol %, and the solid solution has a Y₂O₃ regular hexahedral crystal structure.

### TECHNICAL FIELD

The present invention relates to a deposition material suitable for a plasma etching device member, etc., to be used for semiconductor production, a deposition method using the deposition material, a method for producing a plasma etching device, and a method for producing the deposition material.

### BACKGROUND ART

Plasma etching in the semiconductor production is employed in the step of fabricating a circuit on a wafer. Before initiating plasma etching, the wafer is coated with a photoresist or hard mask (usually an oxide or nitride) and exposed according to a circuit pattern in the photolithography step (patterning step). In plasm etching, plasma etching is applied to the wafer after patterning, whereby the material to be etched is selectively removed (etching step).

The patterning step and the etching step are repeated multiple times in the semiconductor production process. In plasma etching, the material to be etched is removed not only through the physical sputtering effect, but also through the chemical sputtering effect by exposing the wafer to plasma using a halogenated gas of fluorine-type or chlorine-type.

In plasma etching, in order to form highly integrated semiconductor circuits, it is necessary to create approximately vertical profiles, whereby high-energy and high-density ions and radicals are emitted from the plasma. Therefore, not only the wafers to be etched but also the materials constituting the inner surface of the chamber in which etching is conducted, will be affected and worn away by plasma exposure. The particles thus formed, will adhere to the circuitry of the wafer and will thus constitute a factor to reduce the yield in the semiconductor chip production.

In general, the materials to constitute the chamber in which plasma etching is conducted, are usually metallic materials such as aluminum alloys, which do not have high resistance to exposure to halogen gas plasma. Thus, the chamber is covered with a plasma resistant material to prevent the chamber from being abraded by the plasma to generate particles. As the plasma resistant material to cover the chamber, for example, ceramic materials may be mentioned. Ceramic materials such as metal oxides show good durability against exposure to plasma because of their complex crystal structure and high chemical stability.

Among the ceramic materials, particularly yttrium oxide (Y₂O₃) is known to have high plasma resistance to halogen-containing plasmas to be used for production of a semiconductor device. For example, Patent Document 1 proposes a plasma treatment container interior member excellent in plasma erosion resistance, having the surface of a substrate formed of e.g. a metal, a ceramic or a carbon material inside a plasma treatment container covered with a Y₂O₃ thermal spray coating.

Further, Patent Document 2 proposes a method of spray-coating a surface of a semiconductor device or the like with a precursor oxide forming a Y₂O₃-containing solid solution coating by flame spraying, thermal spraying or plasma spraying to obtain a coating having not only plasma resistance but also low electric resistance. It proposes, as the precursor oxide, a mixed oxide of at least two oxides, that is Y₂O₃ and at least one other oxide selected from the group consisting of ZrO₂, CeO₂, HfO₂, Nb₂O₅, Sc₂O₃, Nd₂O₃, Sm₂O₃, Yb₂O₃, Er₂O₃ and a combination thereof.

### PRIOR ART DOCUMENTS

### Patent Documents

Patent Document 1: JP-A-2001-164354
Patent Document 2: JP-A-2010-535288

### DISCLOSURE OF INVENTION

### Technical Problem

In recent years, as is well known, semiconductors to be used in advanced technology fields have become more and more integrated, and the line widths of circuits to be formed on chips are required to be 20 nm or narrower. Thus, even microparticles of several tens nm, which have not been problematic in plasma etching before, now become problematic, and plasma resistance requirements are becoming stricter more than ever.

However, according to studies by the present inventors, the materials disclosed in Patent Document 1 do not sufficiently satisfy high plasma resistance requirements in recent years.

Further, the object of the Y₂O₃-containing solid solution coating formed by thermal spraying described in Patent Document 2 is to achieve low electrical resistivity, which is an electrical property of the coating, and the plasma resistance of the coating is at the same level as Y₂O₃ and is not particularly improved, which is as evident from Patent Document 2. That is, Patent Document 2 illustrates in FIG. 5 the erosion rate indicating the plasma resistance of each of the Y₂O₃-containing solid solution samples 1 to 4 in Table 1, and reports that the plasma resistance of each of the samples 1 to 4 is better than that of conventional materials Al₂O₃, AlN, ZrO₂, etc. but is at the same level as pure Y₂O₃.

Under these circumstances, the object of the present invention is to provide an excellent Y₂O₃-containing solid solution deposition material having higher plasma resistance, suitable as a plasma etching device member used e.g. in semiconductor production process, a deposition method using the deposition material, a method for producing a plasma etching device member, and a method for producing the deposition material.

### Solution to Problem

To achieve the above objects, the present inventers have conducted extensive studies on the plasma resistance of a deposition material containing Y₂O and as a result found a Y₂O₃-containing deposition material comprising a solid solution containing Y₂O₃ and a specific metal oxide, wherein the specific metal oxide is ZrO₂, HfO₂ or Nb₂O₅, the content of the metal oxide contained in the solid solution is within a specific range, and the solid solution has a Y₂O₃ regular hexahedral crystal structure, which has improved plasma resistance and has a lowered erosion (abrasion) rate.

The present invention is accomplished based on such discoveries and provides the following.
(1) A deposition material comprising a solid solution containing a metal oxide selected from ZrO₂, HfO₂ and Nb₂O₅, and Y₂O₃, wherein when the metal oxide is ZrO₂, the ZrO₂ content is from 2 to 12 mol %, when the metal oxide is HfO₂, the HfO₂ content is from 4 to 24 mol %, and when the metal oxide is Nb₂O₅, the Nb₂O₅ content is from 1 to 8 mol %, and the solid solution has a Y₂O₃ regular hexahedral crystal structure.
(2) The deposition material according to (1), wherein when the metal oxide is ZrO₂, the ZrO₂ content is from 7 to 12 mol %.
(3) The deposition material according to (1), wherein when the metal oxide is HfO₂, the HfO₂ content is from 8 to 20 mol %.
(4) The deposition material according to (1), wherein when the metal oxide is Nb₂O₅, the Nb₂O₅ content is from 3 to 7 mol %.
(5) The deposition material according to any one of (1) to (4), wherein the ratio of Zr, Hf or Nb atoms to Y atoms contained in the solid solution is within ±5% relative to the absolute value at 5 points randomly selected in the solid solution contained in the deposition material.
(6) The deposition material according to any one of (1) to (5), wherein the X ray diffraction (XRD) pattern of the solid solution has only peaks of a Y₂O₃ regular hexahedral crystal structure.
(7) A deposition method which comprises thermal spraying using the deposition material as defined in any one of (1) to (6).
(8) A deposition method which comprises physical vapor deposition using the deposition material as defined in any one of (1) to (6).
(9) A method for producing a plasma etching device member, which comprises forming a protective coating on a substrate by the deposition method as defined in (7) or (8).
(10) A method for producing the deposition material as defined in any one of (1) to (9), which comprises subjecting a powder mixture of a Y₂O₃ powder and a metal oxide powder of ZrO₂, HfO₂ or Nb₂O₅ to heat treatment to form a solid solution, wherein when the metal oxide is ZrO₂, the ZrO₂ content in the powder mixture is from 2 to 12 mol % and the heat treatment temperature is from 1000 to 1600° C., when the metal oxide is HfO₂, the HfO₂ content in the powder mixture is from 4 to 24 mol % and the heat treatment temperature is from 1200 to 1600° C., and when the metal oxide is Nb₂O₅, the Nb₂O₅ content in the powder mixture is from 1 to 8 mol % and the heat treatment temperature is from 1200 to 1600° C.
(11) The method for producing the deposition material according to (10), wherein after the solid solution is formed, it is granulated into particles having an average particle size of from 15 to 40 μm, and the particles are subjected to heat treatment at 1200 to 1500° C.
(12) A method for producing the deposition material as defined in any one of (1) to (9), which comprises subjecting a mixed liquid containing a metal oxide sol containing ZrO₂, HfO₂ or Nb₂O₅ and a Y₂O₃ powder, as a raw material, to spray dry granulation, and subjecting the resulting spherical particles formed of primary particles of ZrO₂ fine particles and Y₂O₃ fine particles to heat treatment at 1000 to 1500° C. in an oxidizing atmosphere to form a solid solution.

### Advantageous Effects of Invention

According the present invention, provided are a Y₂O₃-containing solid solution deposition material having high plasma resistance, suitable for forming a device such as a chamber to be subjected to dry etching by plasma generated by a gas containing a halogen such as fluorine, capable of protecting the inner surface of the device from the plasma and suppressing formation of dust during the process, a deposition method using the deposition material, and a method for producing the deposition material.

The present invention further provides a method for producing a plasma etching device member having high plasma resistance, such as a chamber to be subjected to dry etching by plasma generated by a gas containing a halogen such as fluorine.

### BRIEF DESCRIPTION OF DRAWINGS

FIG. 1 illustrates steric relation of Y atoms and oxygen atoms in the crystal lattice structure of Y₂O₃.

FIG. 2 is a binary phase diagram of Y₂O₃ and ZrO₂.

FIG. 3 is a binary phase diagram of Y₂O₃ and HfO₂.

FIG. 4 is a binary phase diagram of Y₂O₃ and Nb₂O₅.

FIG. 5a is an XRD pattern of the solid solution in Example 3.

FIG. 5b is an XRD pattern of the solid solution in Comparative Example 3.

FIG. 6a is an XRD pattern of the solid solution in Example 5.

FIG. 6b is an XRD pattern of the solid solution in Comparative Example 5.

FIG. 7a is an XRD pattern of the solid solution in Example 8.

FIG. 7b is an XRD pattern of the solid solution in Comparative Example 7.

### DESCRIPTION OF EMBODIMENTS

Now, embodiments of the present invention will be described in detail below. In this specification (including claims), in description of numerical ranges, when the units of the upper limit value and the lower limit value are the same, description of the unit of the lower limit may sometimes be omitted, for example, “2 mol % to 12 mol %” may be represented as “2 to 12 mol %”, and “1000° C. to 1600° C.” may be represented as “1000 to 1600° C.”.

### Deposition Material

The coating formed by using the Y₂O₃-containing solid solution deposition material of the present invention has high plasma resistance, which is achieved by the following mechanism.

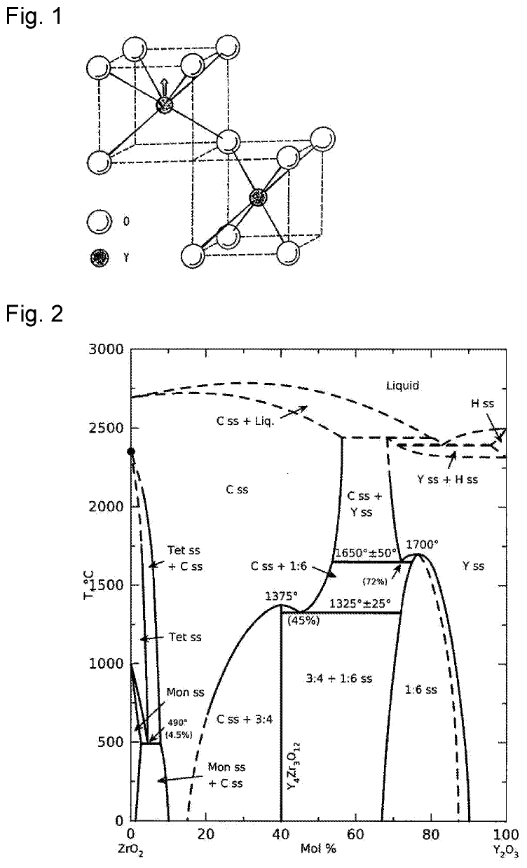

Y₂O₃ which is the main constituent of the deposition material of the present invention is, as described above, widely used e.g. in semiconductor production process and is known as one of materials most highly resistant to plasma containing fluorine. As shown in FIG. 1, even though the Y₂O₃ unit lattice has a regular hexahedral structure which can have eight oxygen atoms coordinated, Y₂O₃ has six oxygen atoms coordinated. The present inventors have thought from the above fact that there are many oxygen vacancies present in the crystal, and by disposing oxygen to the oxygen vacancies by any means to reduce the defects, the plasma resistance of Y₂O₃ may further be improved.

Thus, the present inventors have tried to add another metal oxide to Y₂O₃ to dispose oxygen to the oxygen vacancies to reduce defects. As a result, the present inventors have found that when the metal oxide added to Y₂O₃ satisfies the following two requirements a and b, the abrasion rate of the metal oxide-Y₂O₃ composite solid solution by plasma exposure remarkably decreases and the plasma resistance improves.
a. the metal oxide crystal lattice structure has eight or ten oxygen atoms coordinated.
b. the Y₂O₃ regular hexahedral crystal structure is maintained even when the metal oxide is added in an amount of 1 mol % or more to Y₂O₃.

In the present invention, among the metal oxides to be added to Y₂O₃, ZrO₂ and HfO₂ are metal oxides having eight oxygen atoms coordinated, and Nb₂O₅ is a metal oxide having ten oxygen atoms coordinated.

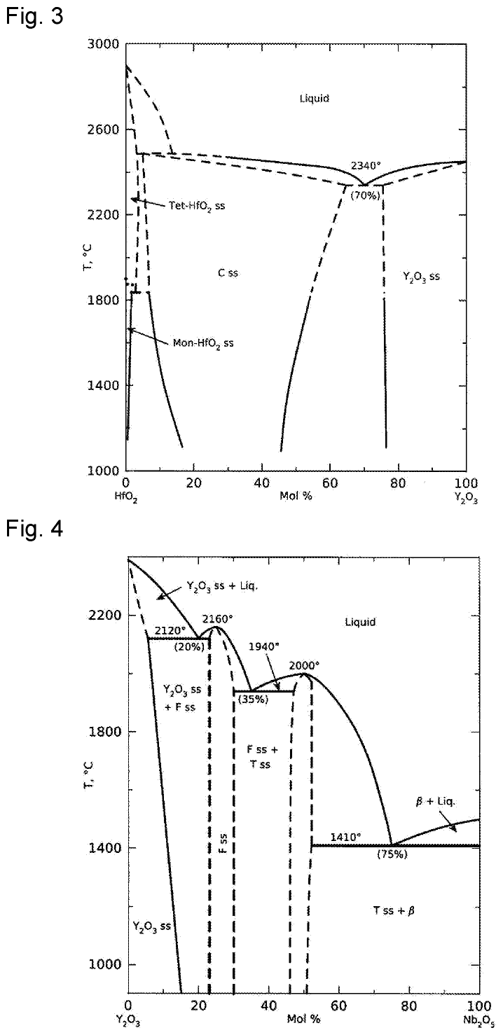

FIG. 2 is a binary phase diagram of Y₂O₃ and ZrO₂, FIG. 3 is a binary phase diagram of Y₂O₃ and HfO₂, and FIG. 4 is a binary phase diagram of Y₂O₃ and Nb₂O₅. It is suggested from these binary phase diagrams that even when ZrO₂, HfO₂ or Nb₂O₅ is added in a small amount to Y₂O₃, the Y₂O₃ regular hexahedral crystal structure is maintained.

ZrO₂ and HfO₂ are metal oxides having eight oxygen atoms coordinated, and tend to release the oxygen atom e.g. by temperature changes. Accordingly, by solid-solubilizing ZrO₂ or HfO₂ in Y₂O₃, oxygen atoms released from ZrO₂ or HfO₂ are disposed to the Y₂O₃ oxygen vacancies to decrease the defects. However, if the amount of ZrO₂ or HfO₂ added is large, Y₂O₃ can no more maintain the regular hexahedral structure, and the plasma resistance decreases resultingly.

Further, Nb₂O₅ is a metal oxide having ten oxygen atoms coordinated, and tends to release the oxygen atom e.g. by temperature changes. Accordingly, by solid-solubilizing Nb₂O₅ in Y₂O₃, oxygen atoms released from Nb₂O₅ are disposed to the Y₂O₃ oxygen vacancies to decrease the defects. However, if the amount of Nb₂O₅ added is large, Y₂O₃ can no more maintain the regular hexahedral structure, and the plasma resistance decreases resultingly.

As described above, by adding, to Y₂O₃, a metal oxide to which eight or ten oxygen atoms are coordinated in such an amount that the Y₂O₃ regular hexahedral crystal structure is maintained, oxygen is introduced to the oxygen vacancies in the crystal, whereby the defect density decreases and the crystal stability improves. It is considered that as a result the resistance of the crystal to physical sputtering and chemical sputtering improves.

The deposition material of the present invention is a material having a metal oxide selected from ZrO₂, HfO₂ and Nb₂O₅ solid-solubilized in Y₂O₃, and the amount of the metal oxide solid-solubilized in Y₂O₃ relates to the plasma resistance and thus is important. The improvement of the plasma resistance of the resulting solid solution tends to be small both when the content of the metal oxide is low and when it is high.

In the present invention, Y₂O₃ may sometimes be referred to as the main oxide and the metal oxide to be added selected form ZrO₂, HfO₂ and Nb₂O₅ as an auxiliary oxide.

In a case where the metal oxide is ZrO₂, the ZrO₂ content in the solid solution is from 2 to 12 mol %, preferably from 7 to 12 mol %, more preferably from 8 to 11 mol %.

In a case where the metal oxide is HfO₂, the HfO₂ content in the solid solution is from 4 to 24 mol %, preferably from 8 to 20 mol %, more preferably from 10 to 16 mol %.

Further, in a case where the metal oxide is Nb₂O₅, the Nb₂O₅ content in the solid solution is from 1 to 8 mol %, preferably from 3 to 7 mol %, more preferably from 4 to 6 mol %.

The solid solution contained in the Y₂O₃-containing solid solution deposition material having high plasma resistance of the present invention has, even though the metal oxide selected from ZrO₂, HfO₂ and Nb₂O₅ is solid-solubilized, the regular hexahedral crystal structure of Y₂O₃ as a raw material. In the present invention, the crystal structure may be confirmed preferably by X-ray diffraction (XRD). When the solid solution has a Y₂O₃ regular hexahedral crystal structure, the X-ray diffraction (XRD) pattern of the solid solution has only peaks of the Y₂O₃ regular hexahedral crystal structure.

In this specification, the X-ray diffraction pattern having only peaks of the Y₂O₃ regular hexahedral crystal structure means that the pattern has the same peaks as those of the Y₂O₃ regular hexahedral crystal structure but has no peak of the metal oxide solid-solubilized in Y₂O₃. In other words, the X-ray diffraction pattern of the Y₂O₃-containing solid solution of the present invention has peaks at the same positions (positions moved in parallel) as the X-ray diffraction pattern of the Y₂O₃ regular hexahedral structure, that is, it has the same shape as the X-ray diffraction pattern of the Y₂O₃ regular hexahedral structure. The intensities of the peaks in both the X-ray diffraction patterns may not necessarily be the same.

### Method for Producing Deposition Material

Now, typical examples of the method for producing the Y₂O₃-containing solid solution deposition material of the present invention will be described.

First, a ZrO₂ powder, a HfO₂ powder or a Nb₂O₅ powder, and a Y₂O₃ powder, are pulverized and mixed by an apparatus such as a rotary ball mil, and the mixture is subjected to high temperature heat treatment e.g. by an electric furnace in air or in an inert atmosphere to be integrated (for example sintered). That is, the method has a step of subjecting the powder mixture of the Y₂O₃ powder and the ZrO₂ powder, the HfO₂ powder or the Nb₂O₅ powder to heat treatment so that the respective powders are integrated.

Here, in the case of the powder mixture of the Y₂O₃ powder and ZrO₂ powder, the ZrO₂ content is from 2 to 12 mol %, preferably from 7 to 12 mol %. In the case of the powder mixture of the Y₂O₃ powder and the HfO₂ powder, the HfO₂ content is from 4 to 24 mol %, preferably from 8 to 20 mol %. In the case of the powder mixture of the Y₂O₃ powder and the Nb₂O₅ powder, the Nb₂O₅ content is from 1 to 8 mol %, preferably from 3 to 7 mol %.

In the Y₂O₃-containing solid solution deposition material of the present invention, the metal oxide added is preferably solid-solubilized uniformly in the deposition material, and according to the production method described later, a uniform deposition material can be obtained.

The uniform deposition material obtained by the present invention is as follows. Five points on solid solution particles contained in the deposition material are randomly selected, and at each point, the content ratio of the metal atoms constituting the added metal oxide to the Y atoms is obtained, and the dispersion of the metal atoms/Y atoms ratio at the 5 points is within ±5% relative to the absolute value. The absolute value here means the theoretical value of the metal atoms/Y atoms assuming that the added metal oxide is uniformly solid-solubilized in the deposition material.

For example, in the case of a deposition material having 10 mol % of ZrO₂ solid-solubilized in Y₂O₃, the absolute value is 0.111, and the deposition material having 10 mol % of ZrO₂ solid-solubilized in Y₂O₃ being uniform means that the values of Zr atoms/Y atoms being within a range of 0.111±0.00555 at all the five randomly selected points.

As a method of obtaining the metal atom content in the solid solution, for example, a method of using an inductively coupled plasma-atomic emission spectrometer may be mentioned. By the added metal oxide being uniformly solid-solubilized in the stage of the deposition material, the metal oxide can be uniformly solid-solubilized even in the coating after deposition, and thus, dispersion of the plasma resistance in the coating can be suppressed.

Now, the method for producing the Y₂O₃-containing solid solution deposition material will be described with reference to a case where the metal oxide is ZrO₂. Also in cases where the metal oxide is HfO₂ or Nb₂O₅, the deposition material can be prepared by a production method in accordance therewith.

The purity of each of the Y₂O₃ powder and the ZrO₂ powder used for pulverization and mixing is preferably 99.5 wt % or higher. The average particle size (D50) of each powder to be pulverized and mixed is preferably 4 μm or less, and the average particle size (D50) of the powder mixture pulverized and mixed is preferably 2 μm or less.

The average particle size of the ZrO₂ powder before the heat treatment is preferably one third or smaller of the average particle size of the Y₂O₃ powder, more preferably one fifth or smaller. The mixing ratio of the ZrO₂ powder is lower than the Y₂O₃ powder, and thus the contact points of the Y₂O₃ powder and the ZrO₂ powder are small accordingly. Thus, the average particle size of the ZrO₂ powder relative to the average particle size of the Y₂O₃ powder is adjusted to be within the above range, whereby the chance of contact of the Y₂O₃ powder and the ZrO₂ powder can be increased. In such a manner, by subjecting the Y₂O₃ powder and the ZrO₂ powder to heat treatment in a state where they are highly brought into contact with each other, solid phase reaction will be promoted, and the ZrO₂ powder can be solid-solubilized in the Y₂O₃ powder in a short time.

The heat treatment when the powder mixture of the Y₂O₃ powder and the ZrO₂ powder is sintered is conducted preferably at 1100° C. to 1600° C., more preferably at 1300 to 1500° C., whereby the solid phase reaction rate of the Y₂O₃ powder and the ZrO₂ powder can be sufficiently high, and further, the particle size of the sintered product after the heat treatment can be adjusted. The heat treatment when the powder mixture of the Y₂O₃ powder and the HfO₂ powder is sintered, or the heat treatment when the powder mixture of the Y₂O₃ powder and Nb₂O₅ powder is sintered, is conducted preferably at 1200 to 1600° C., more preferably at 1400 to 1600° C., whereby the solid phase reaction rate of the Y₂O₃ powder and the HfO₂ powder, or the solid phase reaction rate of the Y₂O₃ powder and the Nb₂O₅ powder can be sufficiently high, and further, the particle size of the sintered product after the heat treatment can be adjusted.

If the heat treatment is conducted at a temperature lower than the above range, the matrix can not sufficiently be uniformalized and further, since the solid phase reaction rate tends to be low, the production time tends to be very long. On the other hand, if the heat treatment is conducted at a temperature higher than the above range, the Y₂O₃ particles tend to be actively sintered with each other and solidified, and thus subsequent particle size control tends to be difficult. The heat treatment time is preferably from 3 to 12 hours, more preferably from 5 to 8 hours.

Then, the synthetic powder sintered by the heat treatment is disintegrated and dispersed in e.g. a solvent to obtain a slurry, which is granulated into spherical particles having an average particle size of preferably from 15 to 40 μm e.g. by spray drying. The resulting granulated particles are heated at preferably 1200 to 1500° C., more preferably at 1350 to 1500° C. e.g. by an electric furnace in an oxidizing atmosphere to remove the organic binder and to improve the breaking strength of the spherical particles, and then used as the deposition material.

The method for producing the deposition material of the present invention is not limited to the above method. As another method, a method of using a fine particles-dispersed sol containing the metal oxide as the dispersoid or a metal salt may be mentioned. For example, a commercial ZrO₂ sol and the Y₂O₃ powder are mixed so that the mixing ratio of Y₂O₃ and ZrO₂ is to be within the above preferred range, and the mixed liquid as a raw material is subjected to spray dry granulation to obtain spherical particles formed of primary particles of ZrO₂ fine particles and Y₂O₃ fine particles. The spherical particles are subjected to heat treatment in an oxidizing atmosphere preferably at 1000 to 1500° C., whereby the reaction treatment for integration and improvement of the breaking strength of the spherical particles can be realized at the same time. The spherical particles after the heat treatment are used as the deposition material. The deposition material may be prepared similarly by using a HfO₂ sol or a Nb₂O₅ sol instead of the ZrO₂ sol.

Production of the deposition material of the present invention may also be conducted by electromelting or grinding method. For example, a mixture of the Y₂O₃ powder and the ZrO₂ powder in a predetermined blend ratio is melted and cast preferably at 3000 to 4000° C. by electromelting, whereby an ingot of the synthetic material in which the Y₂O₃ regular hexahedral crystal structure is maintained by the high temperature history at the time of melting can be obtained. This ingot is sequentially ground by an apparatus such as a jaw crusher or a ball mill into an appropriate particle size range, whereby the particles can be used as the deposition material.

### Deposition Method

As a method of depositing a coating using the deposition material of the present invention, a known method such as thermal spraying or physical vapor deposition method may be mentioned. The respective deposition methods will be described below. The coating formed by thermal spraying method or physical vapor deposition method using the deposition material of the present invention has high plasma resistance.

The thermal spraying method suitable for the present invention may, for example, be atmospheric plasma spraying or vacuum plasma spraying. Atmospheric plasma spraying is particularly preferred. As the atmospheric plasma spraying suitable for the present invention, known one may be used including the device and conditions, and for example, the following may be mentioned.
Thermal spraying device: plasma thermal spray gun (manufactured by Sulzer Metco, 9 MB)
Operating voltage: 65 V
Operating current: 700 A
Primary gas (Ar) flow rate: 60 NL/min
Secondary gas (H₂) flow rate: 5 NL/min
Thermal spraying distance: 140 mm

Physical vapor deposition method suitable for the present invention may, for example, be sputtering, ion plating, arc ion plating or electron beam physical vapor deposition method. Electron beam physical vapor deposition method is particularly preferred. As the electron beam physical vapor deposition method suitable for the present invention, known one may be used including the device and conditions, and for example, the following may be mentioned.
Device: Von Ardenne, Tuba150
Substrate temperature: 450° C.
Chamber pressure: 1.0 Pa
Operating voltage: 60 KW

### Method for Producing Plasma Etching Device Member

The deposition material of the present invention is applicable to e.g. a plasma etching device member used for semiconductor production. The plasma etching device member in the present invention is a member which may be exposed to plasma during plasma process, such as an etching chamber inner material or an electrostatic chuck.

The plasma etching device in the present invention has a cylindrical chamber, a plasma generation member such as an electrode, an electrostatic chuck to hold the wafer, etc. The wafer held by the electrostatic chuck in the chamber is subjected to etching treatment by the action of plasma generated by the plasma generation member. The generated plasma exerts an action not only on the wafer but also the chamber inner member and the electrostatic chuck.

The plasma etching device member in the present invention means a member which may be exposed to plasma, such as the chamber inner member and the electrostatic chuck. Such a plasma etching device member is required to have high plasma resistance, to prevent formation of fine particles due to exposure to plasma. By forming a protective coating by using the deposition material of the present invention on the substrate of the plasma etching device member by thermal spraying or physical vapor deposition method, the plasma etching device member can have high plasma resistance.

### EXAMPLES

Now, the present invention will be described in further detail with reference to Examples. However, it should be understood that the present invention is by no means restricted to the following specific Examples. In the present invention, the average particle size means, unless otherwise specified, a particle size (D50) at accumulated 50% in a particle size distribution measured by laser diffraction/scattering method.

### Example 1

A Y₂O₃ powder having an average particle size of 3.3 μm and a ZrO₂ powder having an average particle size of 1.0 μm were prepared. Both the powders were dryly mixed by a planetary mill (using zirconia balls and zirconia jar) so that the content of the ZrO₂ powder in the obtained mixture of the Y₂O₃ powder and the ZrO₂ powder would be 2 mol %. The obtained powder mixture was heated in an electric furnace at 1500° C. for 10 hours and subjected to solid solution synthesis treatment. Then, the powder after the synthesis treatment was ground by an alumina mortar and an alumina pestle, and the powder after ground was subjected to a discharge plasma sintering device to obtain a sintered product (solid solution).

Then, the surface of the prepared sintered product was polished by a wet emery paper (SiC abrasive grains) to #1200, and the crystal phase was identified by X-ray diffraction (XRD).

Finally, the sintered product subjected to X-ray diffraction was subjected to plasma exposure test to measure the abrasion rate. The abrasion rate was defined by the difference in the height on the surface of the sintered product measured by a laser microscope between the portion masked so as not to be exposed to the plasma and the portion exposed to the plasma.

$$Abrasion rate = difference in height ( μm ) / etching time ( min )$$

In the plasma exposure test, the sintered product was left at rest on a 4 inch Si wafer and exposed to plasma using a dry etching device. Generation of plasma was conducted under the following conditions.

Plasma gas species and flow rate:

| | |
|---|---|
| CF₄: 50 sccm, | O₂: 10 sccm, |
| Ar: 50 sccm | |
| RF output: 800 W, | Bias: 600 W |

### Example 2

In the same manner as in Example 1 except that the content of the ZrO₂ powder in the mixture of the Y₂O₃ powder and the ZrO₂ powder was 5 mol %, a sintered product was prepared, the crystal phase was identified, and the plasma exposure test and measurement of the abrasion rate were conducted.

### Example 3

In the same manner as in Example 1 except that the content of the ZrO₂ powder in the mixture of the Y₂O₃ powder and the ZrO₂ powder was 10 mol %, a sintered product was prepared, the crystal phase was identified, and the plasma exposure test and measurement of the abrasion rate were conducted.

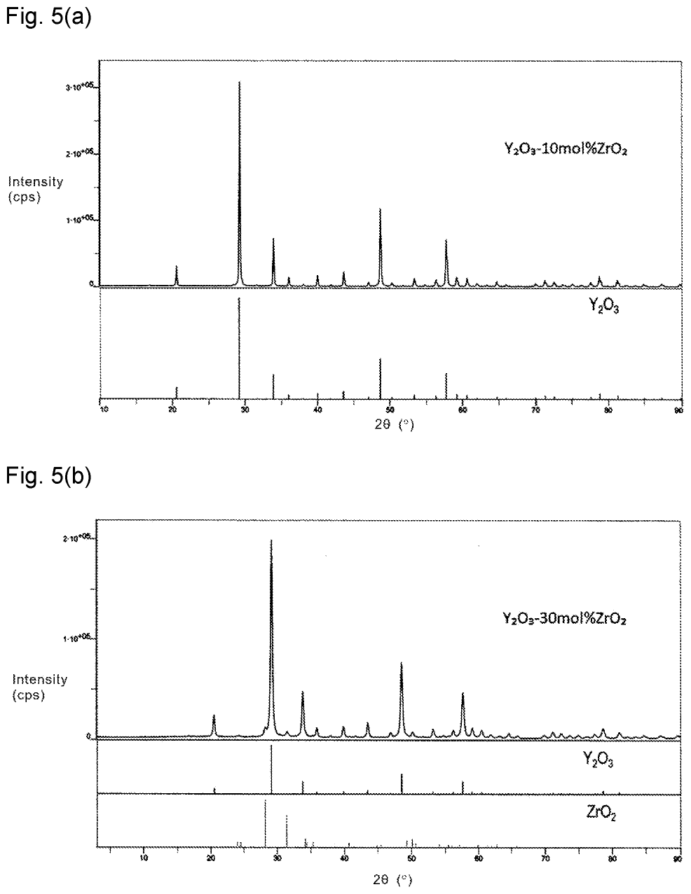

From one particle of the sintered powder obtained in Example 3, five points were randomly selected and the content ratios of Zr atoms to the Y atoms at the respective points were obtained and as a result, they were 0.1123, 0.1088, 0.1075, 0.1115 and 0.1135. Since the absolute value of the material having 10 mol % of ZrO₂ solid-solubilized in Y₂O₃ is 0.111, it was found that in the powder obtained in this Example, ZrO₂ was uniformly solid-solubilized. An XRD pattern used for identification of the crystal phase of the solid solution in Example 3 is shown in FIG. 5(a). It is found from FIG. 5(a) that the XRD pattern of the solid solution in Example 3 has only peaks of the Y₂O₃ regular hexahedral crystal structure.

### Comparative Example 1

In the same manner as in Example 1 except that the content of the ZrO₂ powder in the mixture of the Y₂O₃ powder and the ZrO₂ powder was 15 mol %, a sintered product was prepared, the crystal phase was identified, and the plasma exposure test and measurement of the abrasion rate were conducted.

### Comparative Example 2

In the same manner as in Example 1 except that the content of the ZrO₂ powder in the mixture of the Y₂O₃ powder and the ZrO₂ powder was 20 mol %, a sintered product was prepared, the crystal phase was identified, and the plasma exposure test and measurement of the abrasion rate were conducted.

### Comparative Example 3

In the same manner as in Example 1 except that the content of the ZrO₂ powder in the mixture of the Y₂O₃ powder and the ZrO₂ powder was 30 mol %, a sintered product was prepared, the crystal phase was identified, and the plasma exposure test and measurement of the abrasion rate were conducted. An XRD pattern used for identification of the crystal phase of the solid solution in Comparative Example 3 is shown in FIG. 5(b). It is found from FIG. 5(b) that the XRD pattern of the solid solution in Comparative Example 3 has not only peaks of the Y₂O₃ regular hexahedral crystal structure but also peaks of ZrO₂.

### Example 4

A Y₂O₃ powder having an average particle size of 3.3 μm and a HfO₂ powder having an average particle size of 0.8 μm were prepared. Both the powders were dryly mixed by a planetary mill (using zirconia balls and zirconia jar) so that the content of the HfO₂ powder in the obtained mixture of the Y₂O₃ powder and the HfO₂ powder would be 5 mol %. The obtained powder mixture was heated in an electric furnace at 1500° C. for 10 hours and subjected to solid solution synthesis treatment. Then, the powder after the synthesis treatment was ground by an alumina mortar and an alumina pestle, and the powder after ground was subjected to a discharge plasma sintering device to obtain a sintered product (solid solution). Identification of the crystal phase, the plasma exposure test and the measurement of the abrasion rate were conducted in the same manner as in Example 1.

### Example 5

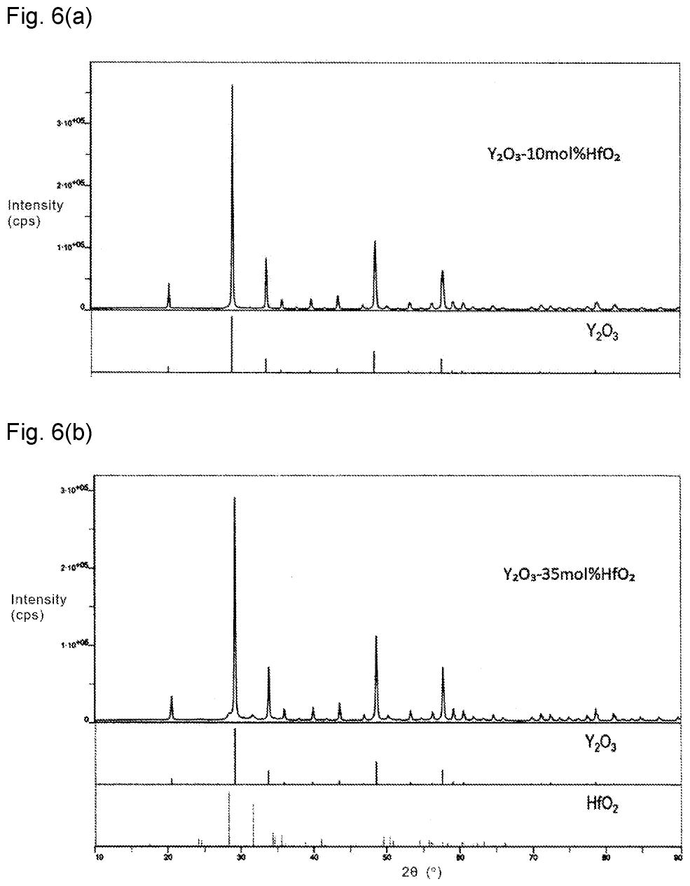

In the same manner as in Example 4 except that the HfO₂ content in the mixture of the Y₂O₃ powder and the HfO₂ powder was 10 mol %, a sintered product was prepared, the crystal phase was identified, and the plasma exposure test and measurement of the abrasion rate were conducted. An XRD pattern used for identification of the crystal phase of the solid solution in Example 5 is shown in FIG. 6(a). It is found from FIG. 6(a) that the XRD pattern of the solid solution in Example 5 has only peaks of the Y₂O₃ regular hexahedral crystal structure.

### Example 6

In the same manner as in Example 4 except that the HfO₂ content in the mixture of the Y₂O₃ powder and the HfO₂ powder was 20 mol %, a sintered product was prepared, the crystal phase was identified, and the plasma exposure test and measurement of the abrasion rate were conducted.

### Comparative Example 4

In the same manner as in Example 4 except that the HfO₂ content in the mixture of the Y₂O₃ powder and the HfO₂ powder was 30 mol %, a sintered product was prepared, the crystal phase was identified, and the plasma exposure test and measurement of the abrasion rate were conducted.

### Comparative Example 5

In the same manner as in Example 4 except that the HfO₂ content in the mixture of the Y₂O₃ powder and the HfO₂ powder was 35 mol %, a sintered product was prepared, the crystal phase was identified, and the plasma exposure test and measurement of the abrasion rate were conducted. An XRD pattern used for identification of the crystal phase of the solid solution in Comparative Example 5 is shown in FIG. 6(b). It is found from FIG. 6(b) that the XRD pattern of the solid solution in Comparative Example 5 has not only peaks of the Y₂O₃ regular hexahedral crystal structure but also peaks of HfO₂.

### Example 7

A Y₂O₃ powder having an average particle size of 3.3 μm and a Nb₂O₅ powder having an average particle size of 0.66 μm were prepared. Both the powders were dryly mixed by a planetary mill (using zirconia balls and zirconia jar) so that the content of the Nb₂O₅ powder in the obtained mixture of the Y₂O₃ powder and the Nb₂O₅ powder would be 2 mol %. The obtained powder mixture was heated in an electric furnace at 1500° C. for 10 hours and subjected to solid solution synthesis treatment. Then, the powder after the synthesis treatment was ground by an alumina mortar and an alumina pestle, and the powder after ground was subjected to a discharge plasma sintering device to obtain a sintered product (solid solution). Identification of the crystal phase, the plasma exposure test and the measurement of the abrasion rate were conducted in the same manner as in Example 1.

### Example 8

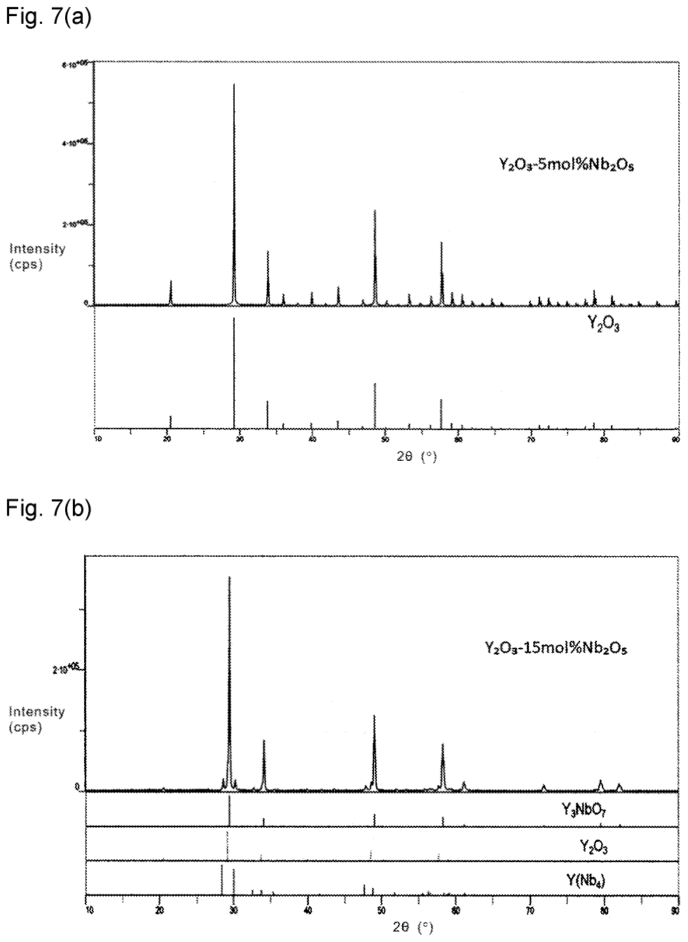

In the same manner as in Example 7 except that the Nb₂O₅ content in the mixture of the Y₂O₃ powder and the Nb₂O₅ powder was 5 mol %, a sintered product was prepared, the crystal phase was identified, and the plasma exposure test and measurement of the abrasion rate were conducted. An XRD pattern used for identification of the crystal phase of the solid solution in Example 8 is shown in FIG. 7(a). It is found from FIG. 7(a) that the XRD pattern of the solid solution in Example 8 has only peaks of the Y₂O₃ regular hexahedral crystal structure.

### Comparative Example 6

In the same manner as in Example 7 except that the Nb₂O₅ content in the mixture of the Y₂O₃ powder and the Nb₂O₅ powder was 10 mol %, a sintered product was prepared, the crystal phase was identified, and the plasma exposure test and measurement of the abrasion rate were conducted.

### Comparative Example 7

In the same manner as in Example 7 except that the Nb₂O₅ content in the mixture of the Y₂O₃ powder and the Nb₂O₅ powder was 15 mol %, a sintered product was prepared, the crystal phase was identified, and the plasma exposure test and measurement of the abrasion rate were conducted. An XRD pattern used for identification of the crystal phase of the solid solution in Comparative Example 7 is shown in FIG. 7(b). It is found from FIG. 7(b) that the XRD pattern of the solid solution in Comparative Example 7 has not only peaks of the Y₂O₃ regular hexahedral crystal structure but also peaks of Nb₂O₅.

### Comparative Example 8

In the same manner as in Example 7 except that the Nb₂O₅ content in the mixture of the Y₂O₃ powder and the Nb₂O₅ powder was 20 mol %, a sintered product was prepared, the crystal phase was identified, and the plasma exposure test and measurement of the abrasion rate were conducted.

### Comparative Example 9

A sintered product was prepared by a discharge plasma sintering device using a Y₂O₃ powder having an average particle size of from 1 to 2 μm. The crystal phase was identified, and the plasma exposure test and measurement of the abrasion rate were conducted in the same manner as in Example 1.

The results of X-ray diffraction and the plasma exposure test in Examples and Comparative Examples are shown in the following Table 1.

With respect to the X-ray diffraction results in Table 1, O indicates that as a result of identification of the crystal phase by means of X-ray diffraction, only peaks of the Y₂O₃ regular hexahedral structure were detected, and X indicates that not only peaks of the Y₂O₃ regular hexahedral structure but also peaks of the metal oxide solid-solubilized in Y₂O₃, peaks of the composite oxide, etc. were detected.

The abrasion rate in Table 1 is a value of the abrasion rate of the test specimen subjected to the plasma exposure test in each of Examples and Comparative Examples, relative to the abrasion rate of a Si wafer subjected to the plasma exposure test being 100.

TABLE 1

| Example/ | | | Amount | X-ray | |
|---|---|---|---|---|---|
| Comparative | Main raw | Auxiliary | added | diffraction | Abrasion |
| Example | material | raw material | (mol %) | results | rate |
| Ex. 1 | Y₂O₃ | ZrO₂ | 2 | ◯ | 8.3 |
| Ex. 2 | | | 5 | ◯ | 8.0 |
| Ex. 3 | | | 10 | ◯ | 7.0 |
| Comp. Ex. 1 | | | 15 | X | 8.5 |
| Comp. Ex. 2 | | | 20 | X | 8.8 |
| Comp. Ex. 3 | | | 30 | X | 10.2 |
| Ex. 4 | | HfO₂ | 5 | ◯ | 8.0 |
| Ex. 5 | | | 10 | ◯ | 7.4 |
| Ex. 6 | | | 20 | ◯ | 7.6 |
| Comp. Ex. 4 | | | 30 | X | 9.0 |
| Comp. Ex. 5 | | | 35 | X | 10.3 |
| Ex. 7 | | NB₂O₅ | 2 | ◯ | 8.1 |
| Ex. 8 | | | 5 | ◯ | 8.0 |
| Comp. Ex. 6 | | | 10 | X | 9.1 |
| Comp. Ex. 7 | | | 15 | X | 9.8 |
| Comp. Ex. 8 | | | 20 | X | 10.2 |
| Comp. Ex. 9 | | Nil | | | 8.7 |

It is found form the results in Table 1 that the abrasion rate of the sintered product (solid solution) in each of Examples 1 to 8 of which only peaks of the Y₂O₃ regular hexahedral crystal structure were detected by the X-ray diffraction, is lower than the abrasion rate of the sintered product in each of Comparative Examples 1 to 9 of which peaks of other metal oxide are detected. That is, by solid-solubilizing ZrO₂, HfO₂ or Nb₂O₅ in Y₂O₃ in a ratio such that the Y₂O₃ regular hexahedral crystal structure is maintained, abrasion by plasma can remarkably be reduced.

Now, Examples of a thermal spray coating obtained by using the deposition material of the present invention will be described.

### Example 9

A Y₂O₃—ZrO₂ slurry was prepared using an aqueous ZrO₂ sol (manufactured by Nissan Chemical Corporation, tradename: NanoUse ZR), a Y₂O₃ powder having an average particle size of 1.5 μm and deionized water. The content ratio of ZrO₂ to the total content of Y₂O₃ and ZrO₂ in the slurry was 10 mol %, and slurry had a total solid content of 45 wt %.

Then, in the slurry, an acrylic binder (manufactured by Chukyo Yushi Co., Ltd., tradename: Celuna WN-405) was added in an amount of 0.40 wt % to the total solid content, and spray dry granulation was conducted to obtain spherical particles having an average particle size of 36 um. The spherical particles were heated to 1350° C. in air using an electric furnace to conduct binder removal and treatment to achieve a uniform composition thereby to prepare a deposition material formed of a solid solution.

Then, a 3 mm-thick 20 mm square substrate formed of an aluminum alloy (A5052) was sand-blasted to have its surface roughened, and on the surface, atmospheric plasma spraying was applied by an atmospheric plasma spraying device (plasma thermal spray gun (manufactured by Sulzer Metco, 9 MB)) at an operating voltage of 65V, with an operating current of 700A, at a primary gas (Ar) flow rate of 60 NL/min, at a secondary gas (H₂) flow rate of 5 NL/min, with a thermal spraying distance of 140 mm, to prepare a test specimen having a thermal spray coating having a thickness of about 0.15 mm formed thereon.

The spray-coated surface of the prepared test specimen was polished by a wet #800 emery paper, cleaned by ultrasonic waves in pure water and dried at 85° C. in a constant temperature chamber, then subjected to the plasma exposure test to obtain the abrasion rate. The abrasion rate was defined by the difference in the height measured by a laser microscope between the portion masked so as not to be exposed to the plasma and the portion exposed to the plasma. For the test, using a dry etching device, the sintered product was left at rest on a wafer and exposed to plasma. Generation of plasma was conducted under the following conditions.

Plasma gas species and flow rate:

| | |
|---|---|
| CF₄: 50 sccm, | O₂: 10 sccm, |
| Ar: 50 sccm | |
| RF output: 800 W, | Bias: 600 W |

### Example 10

A HfO₂ powder having an average particle size of 0.8 μm and a Y₂O₃ powder having an average particle size of 3.3 μm were weighed and mixed so that the content ratio of HfO₂ in the obtained mixture would be 15 mol %. The obtained powder mixture was mixed in ethanol solvent using zirconia balls and a zirconia jar. The mixture was dried and the obtained powder mixture was subjected to heat treatment in an electric furnace at 1500° C. in an air flow to obtain a composite powder having HfO₂ solid-solubilized in Y₂O₃. The composite powder was ground, and the obtained ground product was dispersed in deionized water as a solvent to prepare a slurry having a solid content of 40 wt %.

In the above obtained slurry, an acrylic binder (manufactured by Chukyo Yushi Co., Ltd., tradename: Celuna WN-405) was added in an amount of 0.40 wt % to the solid content, which was subjected to spray dry granulation. As a result, spherical particles having an average particle size of 31 um were obtained. The spherical particles were heated to 1450° C. in air using an electric furnace to conduct binder removal and treatment to achieve a uniform composition thereby to prepare a deposition material. The method of preparing the test specimen and the method of confirming the abrasion rate were the same as in Example 9.

### Comparative Example 10

A Y₂O₃ powder having an average particle size of 3.3 μm was dispersed in deionized water to a solid content of 40 wt % to obtain a slurry. In the obtained slurry, an acrylic binder (manufactured by Chukyo Yushi Co., Ltd., tradename: Celuna WN-405) was added in an amount of 0.40 wt % to the solid content, which was subjected to spray dry granulation to obtain spherical particles having an average particle size of 33 μm. The spherical particles were heated to 1450° C. in air using an electric furnace to conduct binder removal and treatment to achieve a uniform composition thereby to prepare a deposition material. The method of preparing the test specimen and the method of confirming the abrasion rate were the same as in Example 9.

### Comparative Example 11

A Y₂O₃ powder having an average particle size of 3.3 μm and a ZrO₂ powder having an average particle size of 0.9 μm were uniformly mixed so that the ZrO₂ content in the obtained mixture would be 18 mol %, heated to 1450° C. in airflow and ground, and the resulting synthetic powder was dispersed in deionized water at a solid content of 40 wt % to obtain a slurry. In the obtained slurry, an acrylic binder (manufactured by Chukyo Yushi Co., Ltd., tradename: Celuna WN-405) was added in an amount of 0.40 wt % to the solid content, which was subjected to spray dry granulation to obtain spherical particles having an average particle size of 33 μm. The spherical particles were heated to 1450° C. in air using an electric furnace to conduct binder removal and treatment to achieve a uniform composition thereby to prepare a deposition material. The method of preparing the test specimen and the method of confirming the abrasion rate were the same as in Example 9.

The results of the plasma exposure test in each of Examples and Comparative Examples are shown in the following Table 2. The abrasion rate in Table 2 is a value of the abrasion rate of the test specimen subjected to the plasma exposure test in each of Examples and Comparative Examples, relative to the abrasion rate of the Y₂O₃ thermal spray coating subjected to the plasma exposure test in Comparative Example 1 being 100.

TABLE 2

| | | | Content of | |
|---|---|---|---|---|
| | Main | Auxiliary | auxiliary oxide | Abrasion |
| | oxide | oxide | (mol %) | rate |
| Ex. 9 | Y₂O₃ | ZrO₂ | 10 | 78 |
| Ex. 10 | | HfO₂ | 15 | 84 |
| Comp. Ex. 10 | | Nil | — | 100 |
| Comp. Ex. 11 | | ZrO₂ | 18 | 105 |

It is found from the results in Table 2 that the abrasion rate of each of the thermal spray coating in Example 9 and the thermal spray coating in Example 10 is lower than the abrasion rate of the thermal spray coating in Comparative Example 10, whereas the abrasion rate of the thermal spray coating in Comparative Example 11 is higher than the abrasion rate of the thermal spray coating in Comparative Example 10.

### INDUSTRIAL APPLICABILITY

The deposition material of the present invention is useful in a wide range of fields represented by a plasma etching device member using a halogen gas such as a fluorine gas in semiconductor production process.

The entire disclosure of Japanese Patent Application No. 2021-200979 filed on Dec. 10, 2021 including specification, claims, drawings and summary is incorporated herein by reference in its entirety.

1. A deposition material comprising a solid solution comprising:
Y₂O₃, and
a metal oxide selected from the group consisting of ZrO₂, HfO₂ and Nb₂O₅,
wherein:
when the metal oxide is ZrO₂, the ZrO₂ content is from 2 to 12 mol %, when the metal oxide is HfO₂, the HfO₂ content is from 4 to 24 mol %, and when the metal oxide is Nb₂O₅, the Nb₂O₅ content is from 1 to 8 mol %, and
the solid solution has a Y₂O₃ regular hexahedral crystal structure.

2. The deposition material according to claim 1, wherein the metal oxide is ZrO₂, and the ZrO₂ content is from 7 to 12 mol %.

3. The deposition material according to claim 1, wherein the metal oxide is HfO₂, and the HfO₂ content is from 8 to 20 mol %.

4. The deposition material according to claim 1, wherein the metal oxide is Nb₂O₅, and the Nb₂O₅ content is from 3 to 7 mol %.

5. The deposition material according to claim 1, wherein a ratio of Zr, Hf or Nb atoms to Y atoms contained in the solid solution is within ±5% relative to an absolute value at 5 points randomly selected in the solid solution contained in the deposition material.

6. The deposition material according to claim 1, wherein an X ray diffraction (XRD) pattern of the solid solution has only peaks of a Y₂O₃ regular hexahedral crystal structure.

7. A deposition method comprising thermally spraying the deposition material of claim 1.

8. A deposition method comprising physical vapor deposition of the deposition material of claim 1.

9. A method for producing a plasma etching device member, comprising forming a protective coating on a substrate by the deposition method of claim 7.

10. A method for producing the deposition material of claim 1, comprising subjecting a powder mixture of a Y₂O₃ powder and a metal oxide powder of ZrO₂, HfO₂ or Nb₂O₅ to heat treatment to form a solid solution, wherein when the metal oxide is ZrO₂, the ZrO₂ content in the powder mixture is from 2 to 12 mol % and the heat treatment temperature is from 1000 to 1600° C., when the metal oxide is HfO₂, the HfO₂ content in the powder mixture is from 4 to 24 mol % and the heat treatment temperature is from 1200 to 1600° C., and when the metal oxide is Nb₂O₅, the Nb₂O₅ content in the powder mixture is from 1 to 8 mol % and the heat treatment temperature is from 1200 to 1600° C.

11. The method for producing the deposition material according to claim 10, wherein after the solid solution is formed, it is granulated into particles having an average particle size of from 15 to 40 μm, and the particles are subjected to heat treatment at 1200 to 1500° C.

12. A method for producing the deposition material of claim 1, comprising subjecting a mixed liquid containing a metal oxide sol containing ZrO₂, HfO₂ or Nb₂O₅ and a Y₂O₃ powder, as a raw material, to spray dry granulation, and subjecting the resulting spherical particles formed of primary particles of ZrO₂, HfO₂ or Nb₂O₅ fine particles and Y₂O₃ fine particles to heat treatment at 1000 to 1500° C. in an oxidizing atmosphere to form a solid solution.
